(19) United States
(12) Patent Application Publication
(10) Pub. No.: US 2026/0022788 A1
(43) Pub. Date: Jan. 22, 2026

(54) CONNECTOR MODULE, CHASSIS, AND CABINET ASSEMBLY

(71) Applicant: Fulian Precision Electronics (Tianjin) Co., LTD., Tianjin (CN)

(72) Inventors: TUNG-HO SHIH, New Taipei (TW); YI-LIN LIU, New Taipei (TW)

(21) Appl. No.: 18/952,974

(22) Filed: Nov. 19, 2024

(30) Foreign Application Priority Data
Jul. 18, 2024 (CN) 202410967851.7

(51) Int. Cl. F16L 27/093; H05K 7/20

(52) U.S. Cl. CPC F16L 27/093; H05K 7/20781

(57) ABSTRACT

A connector module can be installed in a cabinet having a mating connector, the connector module includes a rotating assembly, a connecting member, a first connector, and a rotating portion. The rotating assembly includes a rotating portion and a connecting nozzle. The rotating portion includes a first channel. The connecting nozzle is connected to the rotating portion and communicates with the first channel. The connecting member is rotatably connected to the rotating portion. The first connector is connected to the connecting member. One end of the first connector connected to the rotating portion and communicating with the first channel, and another end of the first connector configured to connect to an external pipeline. The rotating portion configured to rotate the connecting nozzle from a first position to a second position. The present disclosure further provides a chassis and a cabinet assembly.

### FIELD

The subject matter herein generally relates to servers, and more particularly, to a connector module, a chassis, and a cabinet assembly.

### BACKGROUND

A cabinet may have a number of chassis therein, and each chassis may have a water cooling system. The water cooling system is connected to a mating connector of the cabinet. When a height of the chassis is not in accordance with international standards, the mating connector may be misaligned with the chassis, such that the position of the chassis needs to be adjusted to align with the mating connector, resulting in an excess internal space in the cabinet. Therefore, there is a room for improvement in the art.

### BRIEF DESCRIPTION OF THE DRAWINGS

Implementations of the present technology will now be described, by way of example only, with reference to the attached figures.

FIG. 1 is a diagrammatic view illustrating a connector module in a first position, according to an embodiment of the present disclosure.

FIG. 2 is a diagrammatic view illustrating the connector module of FIG. 1 in a second position.

FIG. 3 is an exploded view illustrating the connector module in FIG. 1.

FIG. 4 is similar to the FIG. 3, but showing the connector module viewed from another angle.

FIG. 5 is a cross-sectional view of the connector module shown in FIG. 1, viewed along a view line V-V indicated in FIG. 1.

FIG. 6 is a diagrammatic view of a cabinet assembly according to an embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

Some embodiments of the present disclosure will be described in detail with reference to the drawings. If no conflict, the following embodiments and features in the embodiments can be combined with each other.

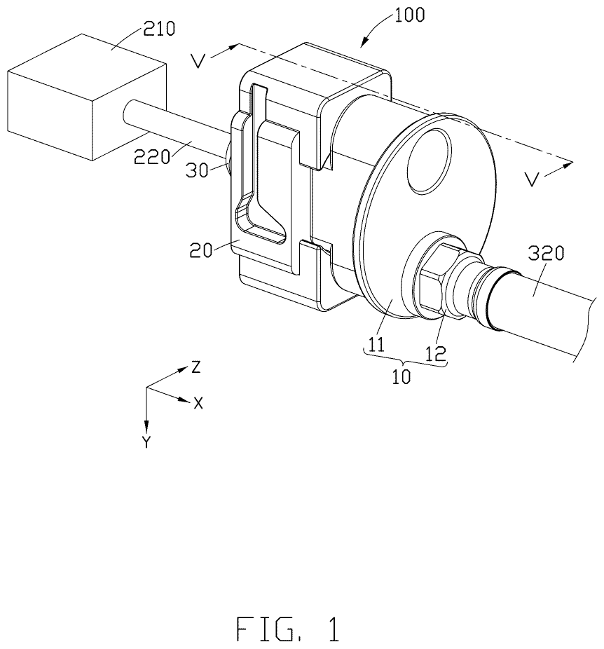

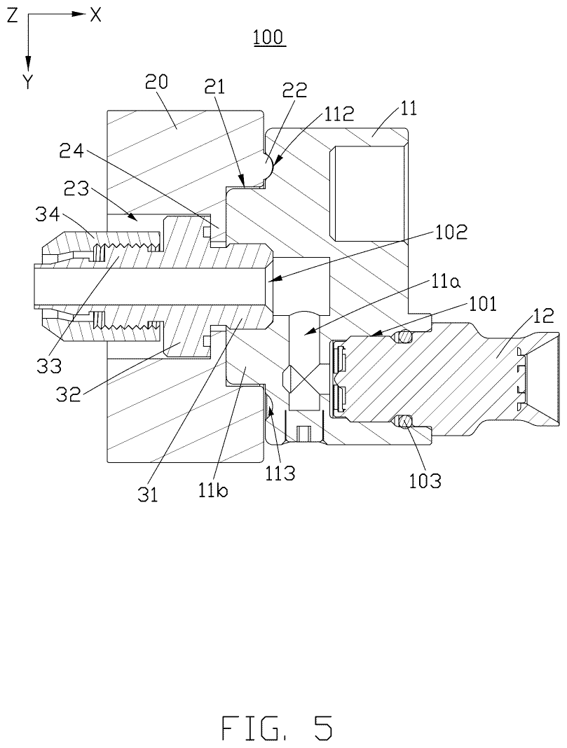

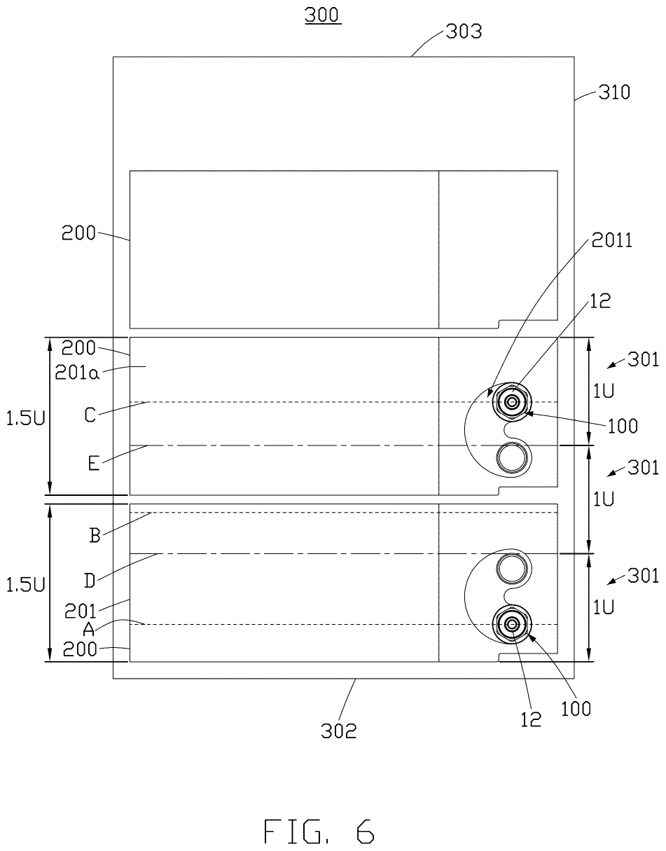

Referring to FIG. 1, a connector module 100 is provided according to an embodiment of the present disclosure. The connector module 100 can be installed in a chassis 200 (shown in FIG. 6) and connect to a mating connector 320 of a cabinet assembly 300 (shown in FIG. 6). The connector module 100 includes a rotating assembly 10, a connecting member 20, and a first connector 30. The rotating assembly 10 includes a rotating portion 11 and a connecting nozzle 12. The rotating portion 11 includes a first channel 11a (shown in FIG. 5), and the connecting nozzle 12 is connected to the rotating portion 11 and communicates with the first channel 11a. The connecting nozzle 12 can connect to the mating connector 320. The connecting member 20 is rotatably connected to the rotating portion 11. The first connector 30 is connected to the connecting member 20. One end of the first connector 30 is connected to the rotating portion 11 and communicates with the first channel 11a, and another end of the first connector 30 can connect to an external pipeline 220 of a water-cooling module 210.

In some embodiments, the rotating portion 11 can rotate the connecting nozzle 12 from a first position to a second position. In an embodiment, the first position is a lowest position of the connecting nozzle 12 along the second direction Y during the rotation of the connecting nozzle 12, and the second position is a highest position of the connecting nozzle 12 along the second direction Y during the rotation of the connecting nozzle 12.

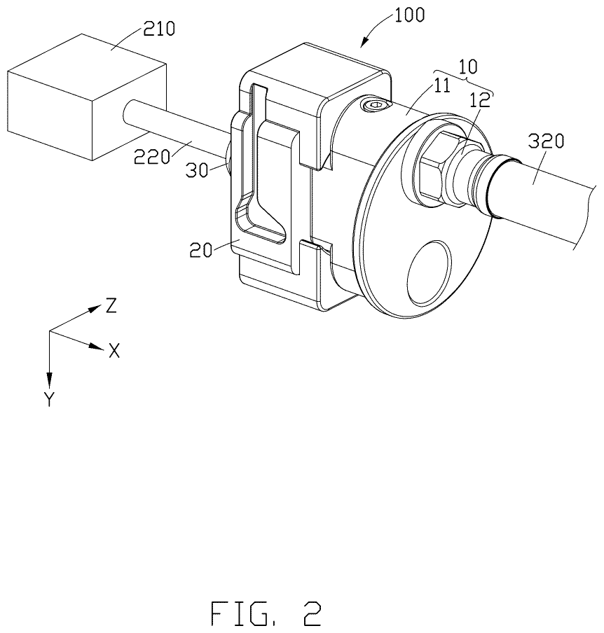

In some embodiments, referring to FIG. 1, the connecting nozzle 12 is disposed in the first position. Referring to FIG. 2, the connecting nozzle 12 is disposed in the second position.

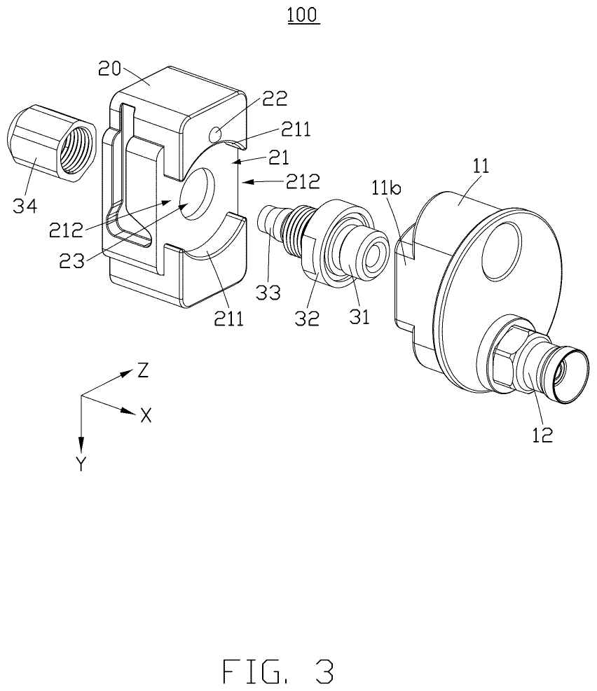

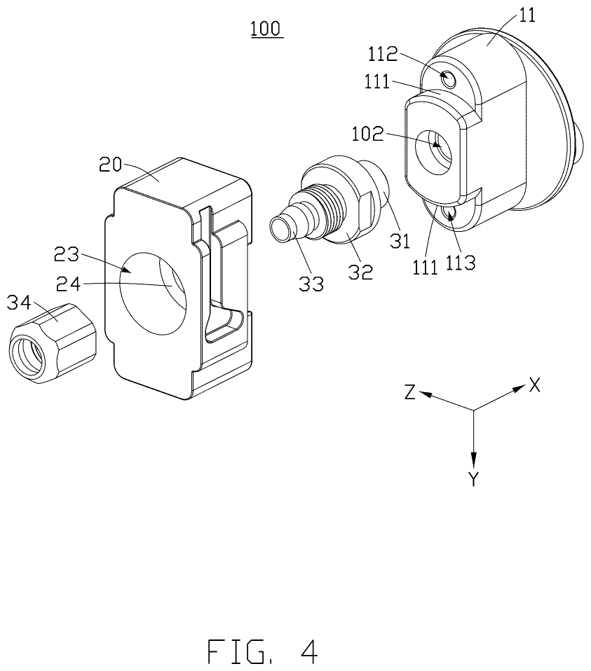

Referring to FIGS. 3 to 5, the first channel 11a includes a first channel opening 101 and a second channel opening 102. The connecting nozzle 12 is connected to the first channel opening 101, and the first connector 30 is connected to the second channel opening 102.

In some embodiments, the connector module 100 further includes a sealing member 103. The sealing member 103 is disposed between the connecting nozzle 12 and the first channel 11a. The sealing member 103 may be a sealing ring made of rubber.

The connecting member 20 and the rotating portion 11 are disposed along a first direction X.

The rotating portion 11 includes a convex portion 11b. The connecting member 20 includes a concave portion 21. The convex portion 11b is rotatably disposed in the concave portion 21.

The convex portion 11b includes two first arc-walls 111. The concave portion 21 includes two second arc-walls 211. Each first arc-wall 111 is connected to one corresponding second arc-wall 211. The first arc-shaped wall 111 and the second arc-shaped wall 211 cooperate with each other, thereby facilitating the rotation of the rotating member 11 relative to the connecting member 20.

The two second arc-walls 211 are disposed along a second direction Y. The first direction X is perpendicular to the second direction Y. When the connecting nozzle 12 is in the first position or the second position, the first arc-wall 111 is in contact with the corresponding second arc-wall 211.

The concave portion 21 defines a cutout 212. A portion of the rotating portion 11 can move outside of the concave portion 21 through the cutout 212 during the rotating portion 11 rotating. The cutout 212 can reduce a friction force between the convex portion 11b and the concave portion 21, thereby facilitating the rotation of the rotating portion 11 relative to the connecting member 20.

The concave portion 21 defines two cutouts 212 disposed along a third direction Z. The first direction X, the second direction Y, and the third direction Z are perpendicular to each other.

When the connecting nozzle 12 is disposed in the first position or the second position, a length of the convex portion 11b along the second direction Y is less than a width of the connecting member 20 along the third direction Z, so that the rotating portion 11 does not extend beyond the connecting member 20 during the rotating portion 11 rotating, thereby reducing interference between the rotating portion 11 and external components.

Referring to FIGS. 3 to 5, the rotating portion 11 includes a first groove 112 and a second groove 113. The connecting member 20 further includes a limiting portion 22. When the connecting nozzle 12 is in the first position, the limiting portion 22 is disposed in the first groove 112. When the connecting nozzle 12 is in the second position, the limiting portion 22 is disposed in the second groove 113, thereby fixing the connecting nozzle 12 and reducing the movement of the connection nozzle 12.

In some embodiments, the limiting portion 22 is elastic. When the rotating portion 11 rotates to the limiting portion 22, the limiting portion 22 presses the limiting portion 22, causing the rotating portion 11 to be compressed. When the connecting nozzle 12 is in the first position, the limiting portion 22 is disposed in the first groove 112; or when the connecting nozzle 12 is in the second position, the limiting portion 22 is disposed in the second groove 113.

In some embodiments, an angle of rotation for the connecting nozzle 12 from the first position to the second position can be 180 degrees, thereby changing a position of the connecting nozzle 12 along the second direction Y.

Referring to FIGS. 2 to 5, in some embodiments, the connecting member 20 further includes an opening 23. The opening 23 extends through the connecting member 20 along the first direction X. A portion of the first connector 30 is disposed in the opening 23.

In some embodiments, when rotating the rotating portion 11, the rotating portion 11 drives the first connector 30 to rotate in the opening 23.

A portion of the first connector 30 extends out of the opening 23 along the first direction X and is connected to the second channel opening 102.

In some embodiments, the connecting member 20 further includes an extended wall 24. The extended wall 24 is disposed in the opening 23. Along the first direction X, a projection of the extended wall 24 overlaps with a projection of the first connector 30, thereby restricting a portion of the first connector 30 in the opening 23 through the extended wall 24.

In some embodiments, the first connector 30 includes a first connecting portion 31. A portion of the first connecting portion 31 is disposed in the opening 23, and another portion of the first connecting portion 31 protrudes out of the opening 23 and is disposed in the second channel opening 102.

In some embodiments, the first connector 30 further includes a second connecting portion 32. The second connecting portion 32 is connected to the first connecting portion 31. Along the first direction X, the second connecting portion 32 is disposed on a side of the extended wall 24 away from the first connecting portion 31. Along the first direction X, a projection of the second connecting portion 32 overlaps with the projection of the extended wall 24.

In some embodiments, the first connector 30 further includes a third connecting portion 33. The third connecting portion 33 is connected to the second connecting portion 32. At least a portion of the third connecting portion 33 is disposed in the opening 23. The external pipeline 220 is connected to the third connecting portion 33.

In some embodiments, the first connector 30 further includes a fourth connecting portion 34. The fourth connecting portion 34 is rotatably connected to the third connecting portion 33. The external pipeline 220 extends through the fourth connecting portion 34 and connects to the third connecting portion 33. The fourth connecting portion 34 enhances a connection strength and stability between the external pipeline 220 and the third connecting portion 33, reducing a risk of leakage caused by the external pipeline 220 deviated from the third connecting portion 33.

Referring to FIG. 6, the chassis 200 is provided according to an embodiment of the present disclosure. The chassis 200 includes the connector module 100, a cabinet body 201, and a water-cooling module 210. The water-cooling module 210 is disposed in the cabinet body 201. A portion of the connector module 100 is disposed in the cabinet body 201. The first connector 30 is connected to the water-cooling module.

In some embodiments, the rotating portion 11 rotates relative to the cabinet body 201, thereby adjusting a position of the connecting nozzle 12 in a thickness direction (that is the second direction Y) of the cabinet body 201.

In some embodiments, the cabinet body 201 includes a first side wall 201a. The first side wall 201a is provided with an arc opening 2011. The connecting nozzle 12 protrudes from the arc opening 2011. The rotating portion 11 drives the connecting nozzle 12 to move in the arc opening 2011, so that the connecting nozzle 12 rotates from the first position to the second position or from the second position to the first position.

In some embodiments, the thickness of the chassis 200 is defined as (n+0.5) U, the n is a natural number greater than or equal to 1. A thickness of the chassis 200 can be any one of 1.5 U, 2.5 U, 3.5 U, 4.5 U, or 5.5 U. Each U has a height of approximately 44.45 millimeters.

Referring to FIG. 6, in some embodiments, the cabinet assembly 300 is provided according to an embodiment of the present disclosure. The cabinet assembly 300 includes a cabinet 310 and a plurality of chassis 200. The cabinet 310 includes a plurality of installation positions 301. A height of each installation positions 301 is 1 U. Each installation position 301 is provided with the mating connector 320. The cabinet 310 can accommodate the chassis 200 therein. The chassis 200 are stacked with each other in sequence in the cabinet 310, and the connecting nozzle 12 of the chassis 200 is connected to the mating connector 320.

When the chassis 200 are stacked with each other in the cabinet 310, the connecting nozzle 12 can be adjusted through the rotating portion 11, so that the connecting nozzle 12 can be connected to the corresponding mating connector 320. The position of the connection nozzle 12 can be adjusted to facilitate the alignment of the connection nozzle 12 with the mating connector 320, thereby avoiding an excess internal space caused by an adjustment of a distance between the chassis 200 to overcome the misalignment of the mating connector 320.

The cabinet 310 includes a bottom wall 302 and a top wall 303 opposite to each other. The installation positions 301 are disposed between the bottom wall 302 and the top wall 303.

Referring to FIG. 6, in one embodiment, the thickness of each chassis 200 is 1.5 U. In the embodiment, the quantity of the chassis 200 is three. From bottom to top, the three chassis 200 are defined as a first chassis 200, a second chassis 200, and a third chassis 200.

A first auxiliary line A, a second auxiliary line B, and a third auxiliary line C are defined. The first auxiliary line A is a height of the mating connector 320 of the first installation position 301, the second auxiliary line B is a height of the mating connector 320 of the second installation position 301, and the third auxiliary line C is a height of the mating connector 320 of the third installation position 301.

A fourth auxiliary line D and a fifth auxiliary line E are further defined. A first installation position 301 is defined between the bottom wall 302 and the fourth auxiliary line D. A second installation position 301 is defined between the fourth auxiliary line D and the fifth auxiliary line E. A third installation position 301 is defined between the fifth auxiliary line E and the third chassis 200.

The connecting nozzle 12 of the first chassis 200 is connected to the mating connector 320 of the first installation position 301. The connecting nozzle 12 of the second chassis 200 is connected to the mating connector 320 of the third installation position 301. Since rotating the connecting nozzle 12 of the second chassis 200, allowing the connecting nozzle 12 to connect to the mating connector 320 of the third installation position 301, thus avoiding the excess internal space caused by moving the second chassis 200 upwards and connecting the connecting nozzle 12 to the mating connector 320 of the third installation position 301, thereby improving the space utilization.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A connector module configured to be installed in a cabinet having a mating connector, the connector module comprising:
a rotating assembly comprising a rotating portion and a connecting nozzle, the rotating portion comprising a first channel, the connecting nozzle connected to the rotating portion and communicating with the first channel, the connecting nozzle configured to be connected to the mating connector;
a connecting member rotatably connected to the rotating portion;
a first connector connecting to the connecting member, one end of the first connector connected to the rotating portion and communicating with the first channel, and another end of the first connector configured to be connected to an external pipeline; and
a rotating portion configured to rotate the connecting nozzle from a first position to a second position.

2. The connector module of claim 1, wherein the connecting member and the rotating portion are disposed along a first direction, the connecting member comprises an opening extending through the connecting member along the first direction, and a portion of the first connector is disposed in the opening.

3. The connector module of claim 2, wherein the connecting member further comprises an extended wall, the extended wall is disposed in the opening, and along the first direction, a projection of the extended wall overlaps with a projection of the first connector.

4. The connector module of claim 1, wherein the rotating portion comprises a convex portion, the connecting member further comprises a concave portion, the convex portion comprises two first arc-walls, the concave portion comprises two second arc-walls, and the convex portion is disposed in the concave portion, and each of the two first arc-wall is connected to one of the two second arc-walls.

5. The connector module of claim 1, wherein the rotating portion comprises a first groove and a second groove, the connecting member further comprises a limiting portion, when the connecting nozzle is in the first position, the limiting portion is disposed in the first groove, and when the connecting nozzle is in the second position, the limiting portion is disposed in the second groove.

6. The connector module of claim 1, wherein the connecting nozzle is configured to rotate by 180 degrees from the first position to the second position.

7. A chassis comprising:
a cabinet body;
a water-cooling module; and
a connector module configured to be installed in a cabinet having a mating connector, the connector module comprising:
a rotating assembly comprising a rotating portion and a connecting nozzle, the rotating portion comprising a first channel, the connecting nozzle connected to the rotating portion and communicating with the first channel, the connecting nozzle configured to be connected to the mating connector;
a connecting member rotatably connected to the rotating portion;
a first connector connecting to the connecting member, one end of the first connector connected to the rotating portion and communicating with the first channel, and another end of the first connector configured to be connected to an external pipeline; and
a rotating portion configured to rotate the connecting nozzle from a first position to a second position;
wherein the connector module and the water-cooling module are disposed in the cabinet body, the first connector is connected to the water-cooling module, and the rotating portion is configured to rotate relative to the cabinet body, thereby adjusting a position of the connecting nozzle in a thickness direction of the cabinet body.

8. The chassis of claim 7, wherein the cabinet body comprises a first side wall, the first side wall defines an arc opening, and the connecting nozzle protrudes from the arc opening.

9. The chassis of claim 7, wherein a thickness of each of the plurality of chassis is defined as (n+0.5) U, the n is a natural number greater than or equal to 1.

10. The chassis of claim 7, wherein the connecting member and the rotating portion are disposed along a first direction, the connecting member comprises an opening extending through the connecting member along the first direction, and a portion of the first connector is disposed in the opening.

11. The chassis of claim 10, wherein the connecting member further comprises an extended wall, the extended wall is disposed in the opening, and along the first direction, a projection of the extended wall overlaps with a projection of the first connector.

12. The chassis of claim 7, wherein the rotating portion comprises a convex portion, the connecting member further comprises a concave portion, the convex portion comprises two first arc-walls, the concave portion comprises two second arc-walls, and the convex portion is disposed in the concave portion, and each of the two first arc-wall is connected to one of the two second arc-walls.

13. The chassis of claim 7, wherein the rotating portion comprises a first groove and a second groove, the connecting member further comprises a limiting portion, when the connecting nozzle is in the first position, the limiting portion is disposed in the first groove, and when the connecting nozzle is in the second position, the limiting portion is disposed in the second groove.

14. The chassis of claim 7, wherein the connecting nozzle is configured to rotate by 180 degrees from the first position to the second position.

15. A cabinet assembly comprising:
a cabinet comprising a plurality of installation positions, a height of each of the plurality of installation positions is 1 U, each of the plurality of installation positions is provided with a mating connector; and
a plurality of chassis, each of the plurality of chassis comprising
a cabinet body;
a water-cooling module; and
a connector module configured to be installed in the cabinet having a mating connector, the connector module comprising:
a rotating assembly comprising a rotating portion and a connecting nozzle, the rotating portion comprising a first channel, the connecting nozzle connected to the rotating portion and communicating with the first channel, the connecting nozzle further connected to the mating connector;
a connecting member rotatably connected to the rotating portion;
a first connector connecting to the connecting member, one end of the first connector connected to the rotating portion and communicating with the first channel, and another end of the first connector configured to be connected to an external pipeline; and
a rotating portion configured to rotate the connecting nozzle from a first position to a second position;
wherein the connector module and the water-cooling module are disposed in the cabinet body, the first connector is connected to the water-cooling module, and the rotating portion is configured to rotate relative to the cabinet body, thereby adjusting a position of the connecting nozzle in a thickness direction of the cabinet body; the plurality of chassis is stacked with each other in the cabinet, and the connecting nozzle is connected to the mating connector.

16. The cabinet assembly of claim 15, wherein the cabinet body comprises a first side wall, the first side wall defines an arc opening, and the connecting nozzle protrudes from the arc opening.

17. The cabinet assembly of claim 15, wherein the connecting member and the rotating portion are disposed along a first direction, the connecting member comprises an opening extending through the connecting member along the first direction, and a portion of the first connector is disposed in the opening.

18. The cabinet assembly of claim 17, wherein the connecting member further comprises an extended wall, the extended wall is disposed in the opening, and along the first direction, a projection of the extended wall overlaps with a projection of the first connector.

19. The cabinet assembly of claim 15, wherein the rotating portion comprises a convex portion, the connecting member further comprises a concave portion, the convex portion comprises two first arc-walls, the concave portion comprises two second arc-walls, and the convex portion is disposed in the concave portion, and each of the two first arc-wall is connected to one of the two second arc-walls.

20. The cabinet assembly of claim 15, wherein the rotating portion comprises a first groove and a second groove, the connecting member further comprises a limiting portion, when the connecting nozzle is in the first position, the limiting portion is disposed in the first groove, and when the connecting nozzle is in the second position, the limiting portion is disposed in the second groove.
